(19) United States
(12) Patent Application Publication
(10) Pub. No.: US 2026/0076220 A1
(43) Pub. Date: Mar. 12, 2026

(54) FAN-OUT WAFER LEVEL PACKAGING UNIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/315,687

(22) Filed: Sep. 1, 2025

(30) Foreign Application Priority Data
Sep. 10, 2024 (TW) 113134233

(51) Int. Cl. H01L 23/00

(52) U.S. Cl. CPC H10W 70/60; H10W 70/09; H10W 72/30; H10W 72/851; H10W 70/6528; H10W 72/874; H10W 90/734

(57) ABSTRACT

A fan-out wafer-level packaging (FOWLP) unit having a substrate, at least one chip, a dielectric layer, at least one conductive circuit, and an outer protective layer is provided. The chip includes a die, chip conductive circuits, a chip dielectric layer, chip bonding pads, a first chip surface, and a second chip surface. The die is electrically connected with the outside through the die pad. The conductive circuits are formed by a metal paste filled into at least one slot of the dielectric layer and grinding of the metal paste. The conductive circuits form a bonding pad in each of openings of the outer protective layer. The chip is electrically connected to the outside through the bonding pads located around a chip area on the second chip surface of the chip. Thereby problems of the FOWLP module available now including higher manufacturing cost and less environmental benefit can be solved.

### CROSS-REFERENCE TO RELATED APPLICATIONS

This non-provisional application claims priority under 35 U.S.C. § 119(a) on Patent Application No(s). 113134233 filed in Taiwan, R.O.C. on Sep. 10, 2024, the entire contents of which are hereby incorporated by reference.

### BACKGROUND OF THE INVENTION

The present invention relates to a packaging unit, especially to a fan-out wafer level packaging (FOWLP) unit.

The packaging techniques with high efficiency and high reliability is a trend in semiconductor industry. FOWLP is one of the packaging techniques available now.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree, the most critical point is the manufacturing of the respective conductive circuits in the RDL.

However, the formation of the respective conductive circuits in the RDL of the FOWLP technology available now is by chemical plating or electroplating. Thus not only cost for material and manufacturing is high, the manufacturing process is also not environmental friendly.

Most of the FOWLP technology available now focuses on the design of the die. No design specific to the chip (formed by cutting of the wafer after completing RDL on the chip) is provided. Thus there is room for improvement and there is a need to provide a novel design of the chip in the FOWLP unit.

### SUMMARY OF THE INVENTION

Therefore, it is a primary object of the present invention to provide a fan-out wafer-level packaging (FOWLP) unit which includes a substrate, at least one chip, a dielectric layer, at least one conductive circuit, and an outer protective layer. The chip consists of a die, a plurality of chip conductive circuits, a chip dielectric layer, a plurality of chip bonding pads, a first chip surface, and a second chip surface. The die is electrically connected with the outside through the die pad. The conductive circuits are formed by a metal paste filled into at least one slot of the dielectric layer and grinding of the metal paste. The conductive circuits form a bonding pad in each of openings of the outer protective layer. The chip is electrically connected to the outside through the bonding pads located around a chip area on the second chip surface of the chip. Thereby problems of the FOWLP module available now generated during manufacturing of the respective conductive circuits including higher manufacturing cost and less environmental benefit can be solved.

In order to achieve the above object, a FOWLP unit according to the present invention includes a substrate, at least one chip, a dielectric layer, at least one conductive circuit, and an outer protective layer. The substrate is provided with a first surface and a second surface opposite to the first surface. The chip consists of a die, a plurality of chip conductive circuits, a chip dielectric layer, a plurality of chip bonding pads, a first chip surface, and a second chip surface. The chip is arranged at the substrate by the first chip surface. The chip bonding pads are disposed on the second chip surface and a range perpendicular to the second chip surface of the chip is defined as a chip area. The die is provided with at least one die pad so that the die is electrically connected with the outside through the die pad, the chip conductive circuits, and the chip bonding pads in turn. The dielectric layer is mounted to the second surface of the substrate and covering the chip. At least one slot extending horizontally is formed on the dielectric layer and used for allowing the corresponding chip bonding pad to be exposed. The conductive circuits are formed by a metal paste filled into the slots and are electrically connected to the chip bonding pads. The outer protective layer is arranged over the dielectric layer and the conductive circuit and having a plurality of openings. At least one of the openings is located around the chip area on the second chip surface of the chip. The conductive circuits are exposed through the openings correspondingly to form a bonding pad in each of the openings. The chip is electrically connected with the outside through the chip bonding pads, the conductive circuits, and the bonding pads located around the chip area on the second chip surface of the chip in turn to form the FOWLP unit. A method of manufacturing the FOWLP unit includes the following steps. Step S1: providing a substrate having a first surface and a second surface opposite to each other. Step S2: disposing a plurality of chips on the second surface of the substrate with an interval between the two adjacent chip. The chip consists of a die, a plurality of chip conductive circuits, a chip dielectric layer, a plurality of chip bonding pads, a first chip surface, and a second chip surface. The chip is arranged at the substrate by the first chip surface. The chip bonding pads are disposed on the second chip surface and a range perpendicular to the second chip surface of the chip is defined as a chip area. The die is provided with at least one die pad. Thus the die is electrically connected with the outside through the die pad, the chip conductive circuits, and the chip bonding pads in turn. Step S3: disposing a dielectric layer on the second surface of the substrate and allowing the dielectric layer covering the chip. The dielectric layer is provided with at least one slot extending in a horizontal direction and used for allowing the chip bonding pad to be exposed. Step S4: filling a metal paste into the slot of the dielectric layer and allowing a level of the metal paste higher than a surface of the dielectric layer. Step S5: grinding the metal paste with the level higher than the surface of the dielectric layer to make a surface of the metal paste flush with the surface of the dielectric layer and form a plurality of conductive circuits. Step S6: paving an outer protective layer over the dielectric layer. Step S7: forming a plurality of openings on the outer protective layer and allowing at least one of the openings to be located around the chip area on the second chip surface of the chip so that the conductive circuit are exposed through the openings to form a bonding pad in each of the openings. Step S8: performing cutting to form a plurality of FOWLP units.

Preferably, a bump is mounted in each of the openings and disposed on the bonding pad.

Preferably, a solder ball is disposed on each of the bumps.

Preferably, the FOWLP unit is electrically connected and mounted to a printed circuit board (PCB) by the solder balls.

Preferably, the chip is produced by RDL packaging technology. The respective chip conductive circuits are formed by a plurality of first conductive circuits and a plurality of second chip conductive circuits. The chip dielectric layer consists of a first dielectric layer and a second dielectric layer. The first conductive circuits are formed by a metal paste filled into the at least one slot of the first dielectric layer and electrically connected to the die pads of the die. The second conductive circuits are formed by a metal paste filled into the at least one slot of the second dielectric layer and electrically connected to the first conductive circuits. A method of manufacturing the chip further includes the following steps. Step S1: providing a wafer having a plurality of dies each of which is provided with at least one die pad; Step S2: disposing a first dielectric layer over the dies and forming at least one slot on the first dielectric layer; Step S3: filling a metal paste into the slot of the first dielectric layer and allowing a level of the metal paste higher than a surface of the first dielectric layer; Step S4: grinding the metal paste with the level higher than the surface of the surface of the first dielectric layer to make a surface of the metal paste flush with the surface of the first dielectric layer and form a plurality of first conductive circuits which are electrically connected to the die pads of the dies; Step S5: arranging a second dielectric layer over the first dielectric layer and forming at least one slot on the second dielectric layer; Step S6: filling a metal paste into the slot of the second dielectric layer and allowing a level of the metal paste higher than a surface of the second dielectric layer; Step S7: grinding the metal paste with the level higher than the surface of the surface of the second dielectric layer to make a surface of the metal paste flush with the surface of the second dielectric layer and form a plurality of second conductive circuits which are electrically connected to the first conductive circuits; and Step S8: performing cutting and diving the wafer into a plurality of chips; the first conductive circuits and the second conductive circuits are combined to form a plurality of chip conductive circuits; a chip dielectric layer is formed by the first dielectric layer and the second dielectric layer.

Preferably, the metal pastes which form the first conductive circuits and the second conductive circuits include silver paste, nano-scale silver paste, copper paste, and nano-scale copper paste.

Preferably, the substrate includes a silicon substrate, a glass substrate, and a ceramic substrate.

Preferably, the first chip surface of the chip is disposed on the second surface of the substrate by a die attach film (DAF).

### BRIEF DESCRIPTION OF THE DRAWINGS

FIG. 1 is a side sectional view of an embodiment of a FOWLP unit according to the present invention;

FIG. 2 is a side sectional view of a first embodiment according to the present invention;

FIG. 3 is a side sectional view showing a chip disposed on a substrate of the embodiment in FIG. 2 according to the present invention;

FIG. 4 is a side sectional view showing a first dielectric layer disposed over the substrate and the chip of the embodiment in FIG. 3 according to the present invention;

FIG. 5 is a side sectional view showing slots filled with a metal paste therein of the embodiment in FIG. 4 according to the present invention;

FIG. 6 is a side sectional view showing grinding of the metal paste to form conductive circuits of the embodiment in FIG. 5 according to the present invention;

FIG. 7 is a side sectional view showing an outer protective layer arranged at the conductive circuits of the embodiment in FIG. 6 according to the present invention;

FIG. 8 is a side sectional view showing a bump mounted to a bonding pad of the embodiment in FIG. 7 according to the present invention;

FIG. 9 is a side sectional view showing a solder ball arranged at the bump of the embodiment in FIG. 8 according to the present invention;

FIG. 10 is an enlarged sectional view of a chip of an embodiment according to the present invention;

FIG. 11 is an enlarged sectional view of a die of a chip of an embodiment according to the present invention;

FIG. 12 is a sectional view showing a first dielectric layer disposed over the die of the embodiment in FIG. 11 according to the present invention;

FIG. 13 is a sectional view showing a metal paste filled into slots of the first dielectric layer of the embodiment in FIG. 12 according to the present invention;

FIG. 14 is a sectional view showing grinding of the metal paste of the embodiment in FIG. 13 to form first conductive circuits according to the present invention;

FIG. 15 is a sectional view showing a second dielectric layer disposed over the first dielectric layer of the embodiment in FIG. 14 according to the present invention;

FIG. 16 is a sectional view showing a metal paste filled into slots of the second dielectric layer of the embodiment in FIG. 15 according to the present invention.

### DETAILED DESCRIPTION OF THE PREFFERED EMBODIMENT

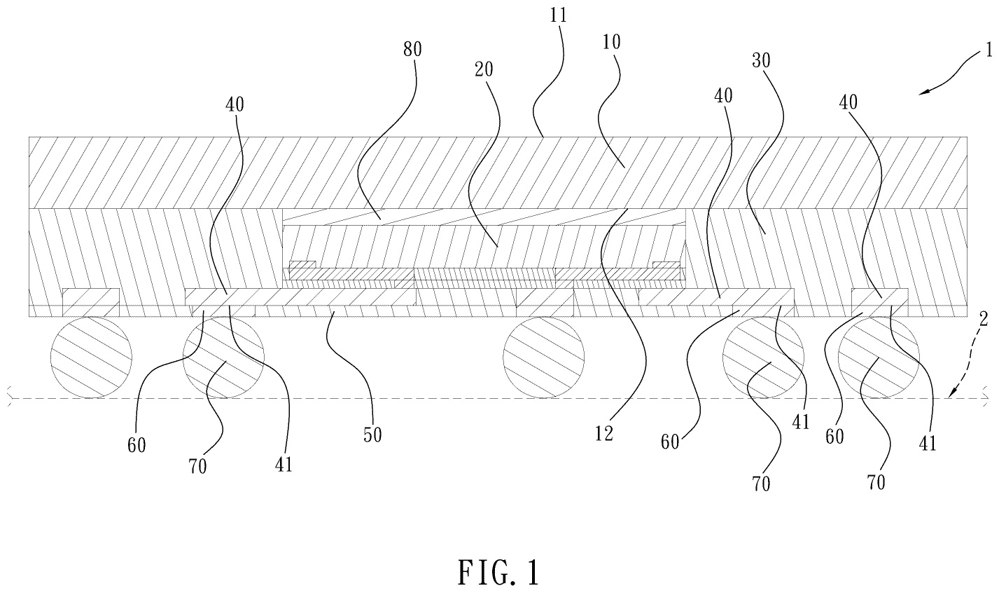

Refer to FIG. 1, a fan-out wafer-level packaging (FOWLP) unit 1 according to the present invention is provided. The FOWLP unit 1 includes a substrate 10, at least one chip 20, a dielectric layer 30, at least one conductive circuit 40, and an outer protective layer 50.

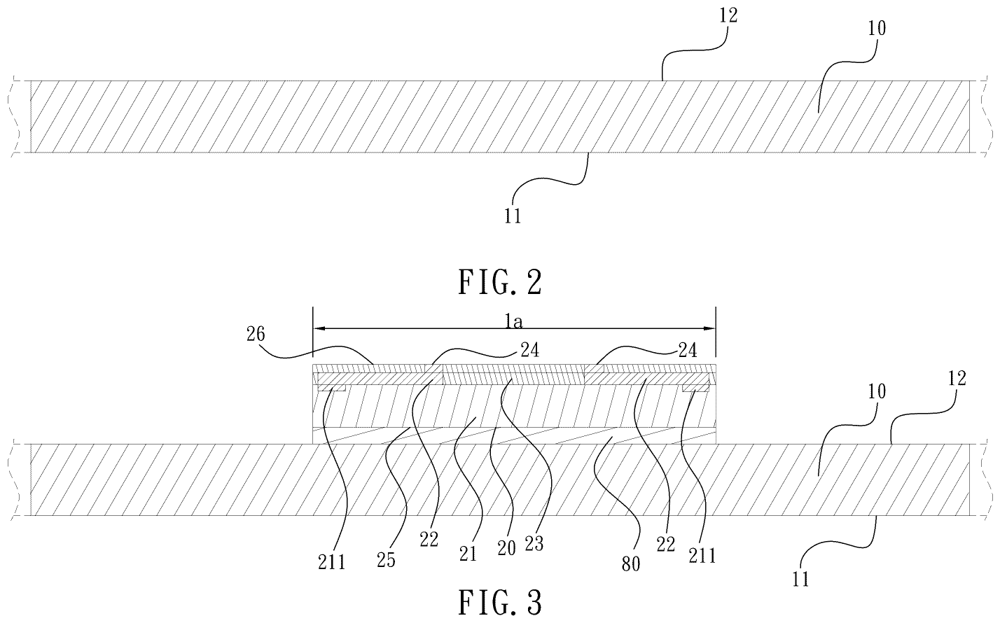

As shown in FIG. 2, the substrate 10 is provided with a first surface 11 and a second surface 12 opposite to the first surface 11.

The chip 20 consists of a die 21, a plurality of chip conductive circuits 22, a chip dielectric layer 23, a plurality of chip bonding pads 24, a first chip surface 25, and a second chip surface 26, as shown in FIG. 3. The chip 20 is arranged at the substrate 10 by the first chip surface 25. The chip bonding pads 24 are disposed on the second chip surface 26 and a range perpendicular to the second chip surface 26 of the chip 20 is defined as a chip area 1a, as shown in FIG. 3. The die 21 is provided with at least one die pad 211 so that the die 21 is electrically connected with the outside through the die pad 211, the chip conductive circuits 22, and the chip bonding pads 24 in turn, as shown in FIG. 3.

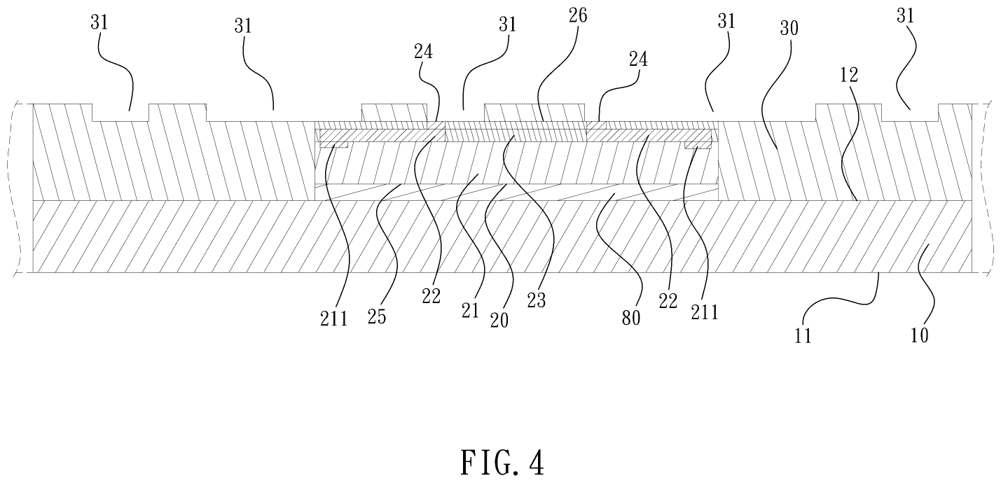

Refer to FIG. 4, the dielectric layer 30 is mounted to the second surface 12 of the substrate 10 and covering the chip 20. At least one slot 31 extending horizontally is formed on the dielectric layer 30 and used for allowing the corresponding chip bonding pad 24 to be exposed.

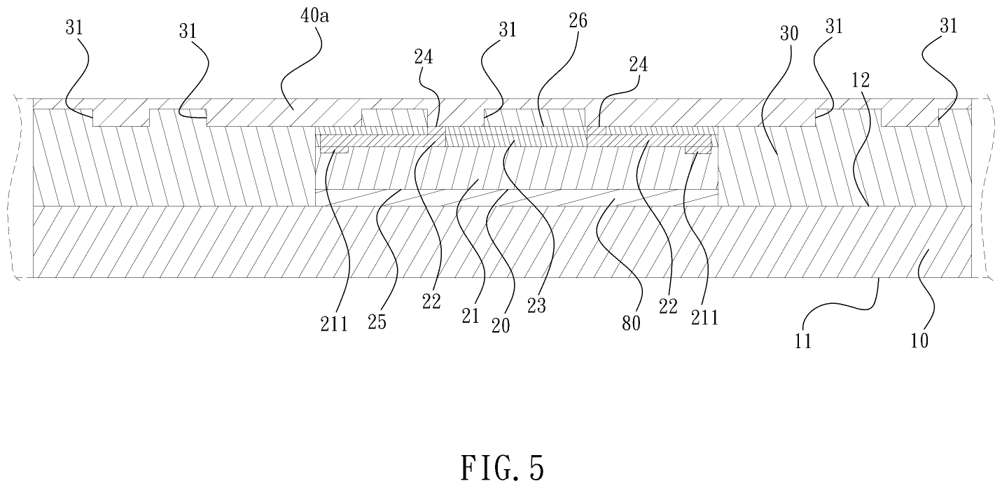

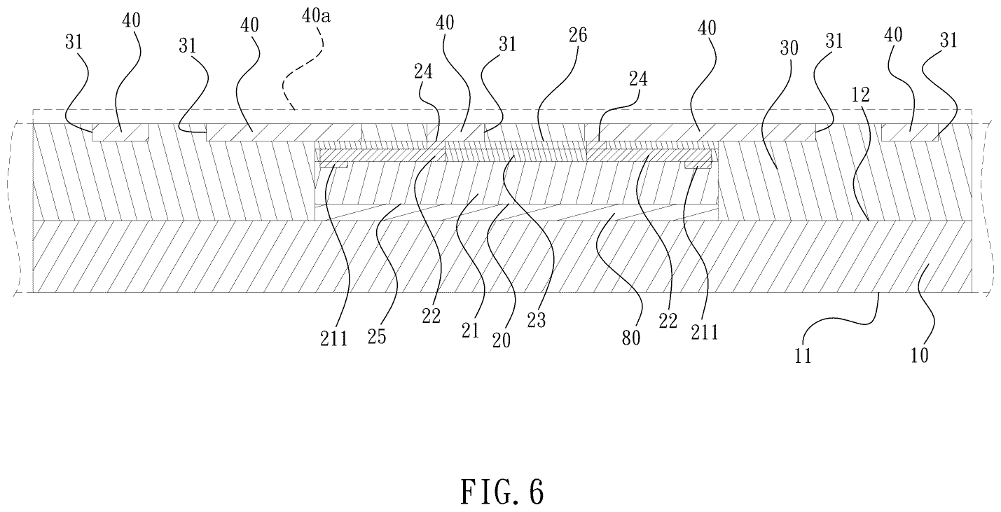

The conductive circuits 40 are formed by a metal paste 40a filled into the slots 31, as shown in FIG. 5. The conductive circuits 40 are electrically connected to the chip bonding pads 24, as shown in FIG. 6.

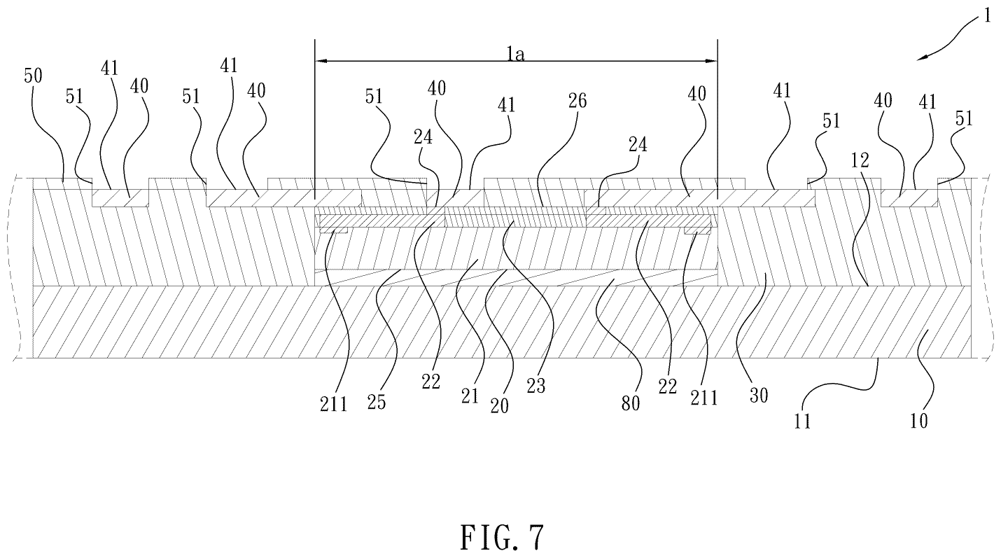

Refer to FIG. 7, the outer protective layer 50 is arranged over the dielectric layer 30 and the conductive circuits 40 and provided with a plurality of openings 51. At least one of the openings 51 is located around the chip area 1a on the second chip surface 25 of the chip 20. The conductive circuits 40 are exposed through the openings 51 correspondingly to form a bonding pad 41 in each of the openings 51. In FIG. 7, there are five bonding pads 41 in the FOWLP unit 1, but not limited.

The chip 20 is electrically connected with the outside through the chip bonding pads 24, the conductive circuits 40, and the bonding pads 41 located around the chip area 1a on the second chip surface 25 of the chip 20 in turn to form the FOWLP unit 1, as shown in FIG. 7.

A method of manufacturing the FOWLP Unit 1 includes the following steps.
Step S1: providing a substrate 10 having a first surface 11 and a second surface 12 opposite to each other, as shown in FIG. 2.
Step S2: disposing a plurality of chips 20 on the second surface 12 of the substrate 10 with an interval between the two adjacent chips 20, as shown in FIG. 3. The chip 20 consists of a die 21, a plurality of chip conductive circuits 22, a chip dielectric layer 23, a plurality of chip bonding pads 24, a first chip surface 25, and a second chip surface 26. The chip 20 is arranged at the substrate 10 by the first chip surface 25. The chip bonding pads 24 are disposed on the second chip surface 26 and a range perpendicular to the second chip surface 26 of the chip 20 is defined as a chip area 1a. The die 21 is provided with at least one die pad 211. Thus the die 21 is electrically connected with the outside through the die pad 211, the chip conductive circuits 22, and the chip bonding pads 24 in turn, as shown in FIG. 3.
Step S3: disposing a dielectric layer 30 on the second surface 12 of the substrate 10 and allowing the dielectric layer 30 covering the chip 20. The dielectric layer 30 is provided with at least one slot 31 extending in a horizontal direction and used for allowing the chip bonding pad 24 to be exposed, as shown in FIG. 4.
Step S4: filling a metal paste 40a into the slot 31 of the dielectric layer 30 and allowing a level of the metal paste 40a higher than a surface of the dielectric layer 30, as shown in FIG. 5.
Step S5: grinding the metal paste 40a with the level higher than the surface of the dielectric layer 30 to make a surface of the metal paste 40a flush with the surface of the dielectric layer 30 and form a plurality of conductive circuits 40, as shown in FIG. 6.
Step S6: paving an outer protective layer 50 OVER the dielectric layer 30, as shown in FIG. 7.
Step S7: forming a plurality of openings 51 on the outer protective layer 50 and allowing at least one of the openings 51 to be located around the chip area 1a on the second chip surface 26 of the chip 20 so that the conductive circuit 40 can be exposed through the opening 51 to form a bonding pad 41 in the opening 51, as shown in FIG. 7.
Step S8: performing cutting to form a plurality of FOWLP units 1, as shown in FIG. 7.

The step S3, step S4, and the step S5 of the present method of manufacturing the FOWLP unit 1 are considered as key steps in production of RDL of the FOWLP unit 1 and all are precise and easily-implemented steps. Thus the manufacturing process is simplified so that a certain degree of compact design still can be achieved under condition that the conductive circuits in the RDL have electrical extension in the XY plane and interconnections.

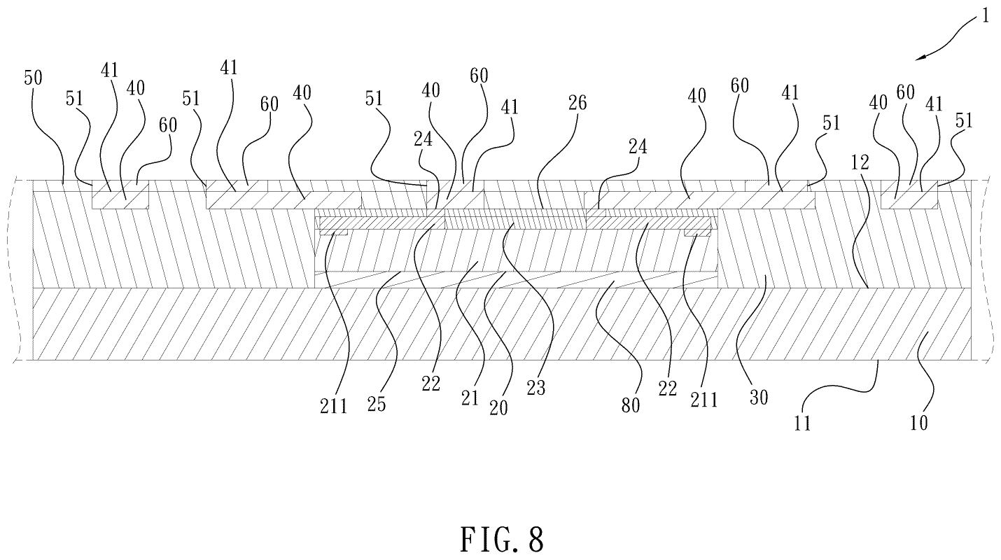

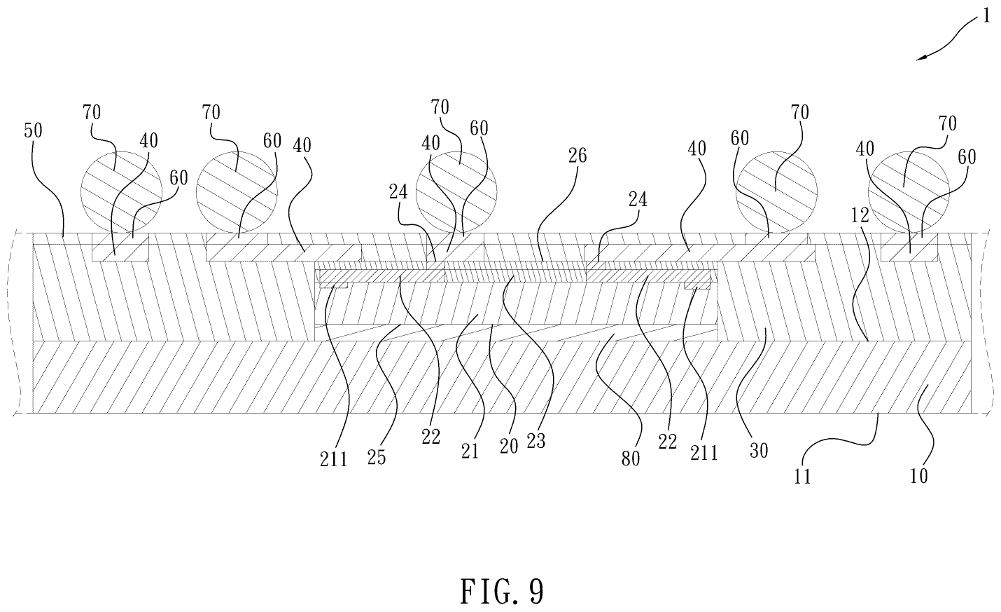

Refer to FIG. 8, a bump 6 is mounted in each of the openings 51 and disposed on the bonding pad 41 for protection of the bonding pad 41 and increasing of product yield. Refer to FIG. 9, a solder ball 60 is disposed on each of the bumps 6.

Refer to FIG. 1, the FOWLP unit 1 is electrically connected and mounted to a printed circuit board (PCB) 2 by the solder balls 70 so that products are more diverse.

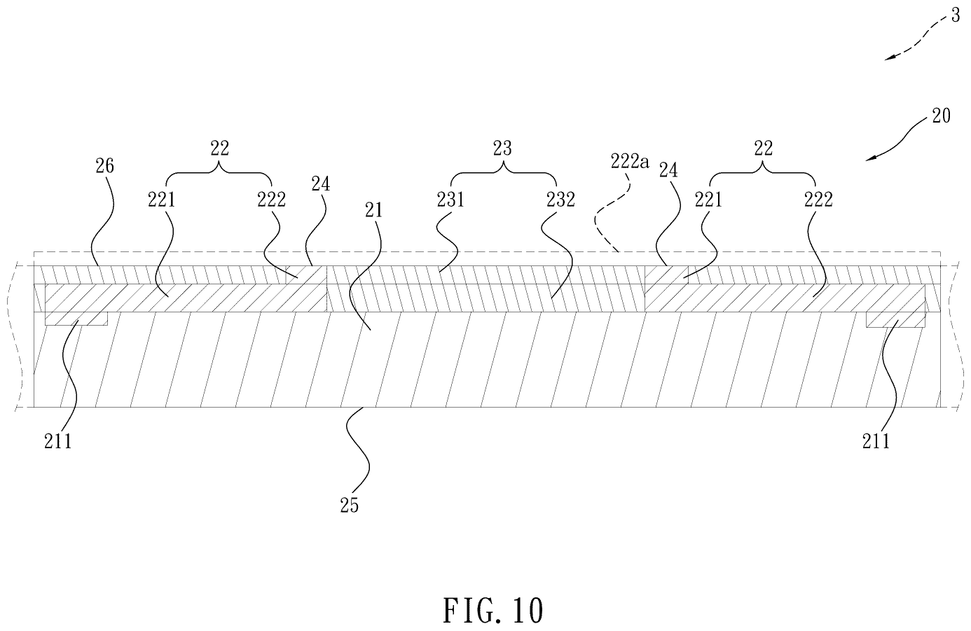

Refer to FIG. 10, the chip 20 is produced by RDL packaging technology, instead of chemical plating or electroplating available now. The respective chip conductive circuits 22 are formed by a plurality of first conductive circuits 221 and a plurality of second chip conductive circuits 222. The chip dielectric layer 23 consists of a first dielectric layer 231 and a second dielectric layer 232. The first conductive circuits 221 are formed by a metal paste 221a filled into the at least one slot 2311 of the first dielectric layer 231 and electrically connected to the die pads 211 of the die 21. The second conductive circuits 222 are formed by a metal paste 222a filled into the at least one slot 2321 of the second dielectric layer 232 and electrically connected to the first conductive circuits 221.

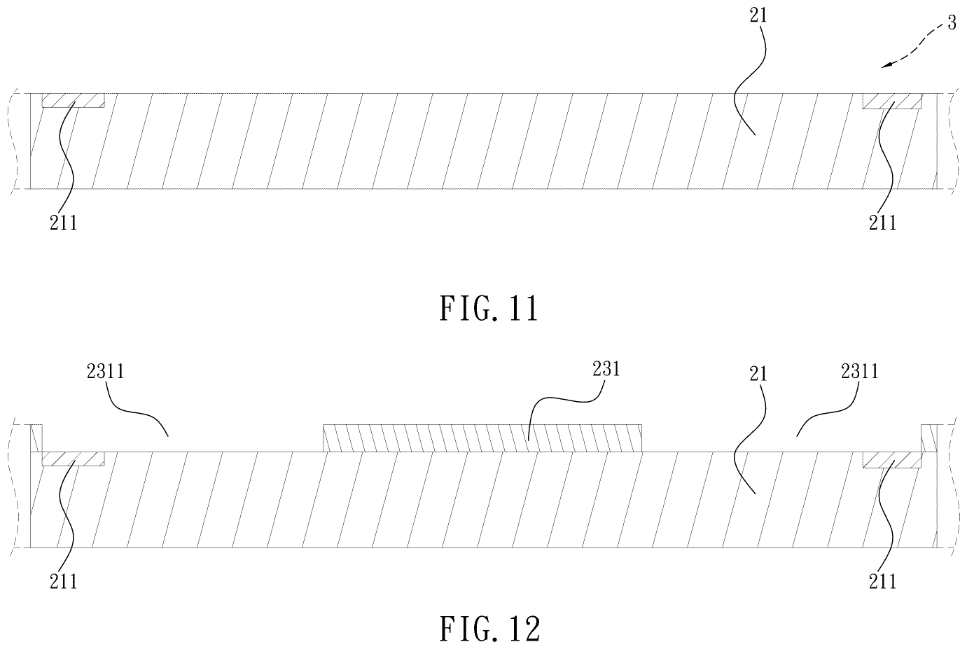

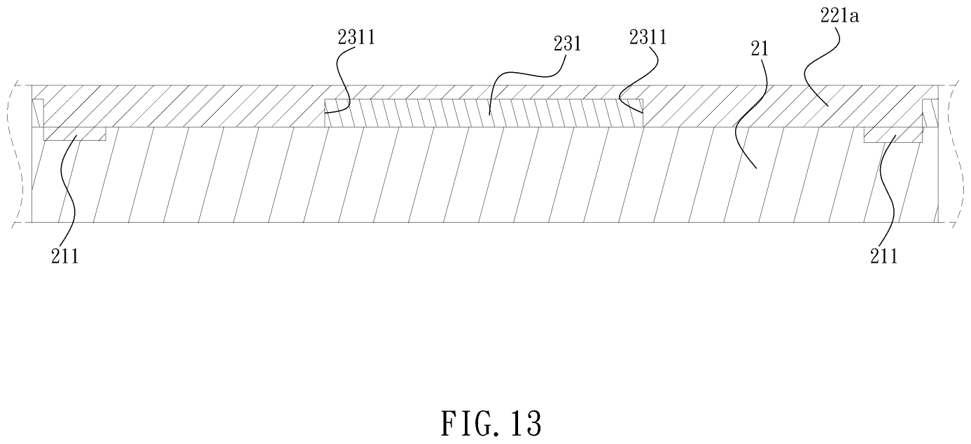

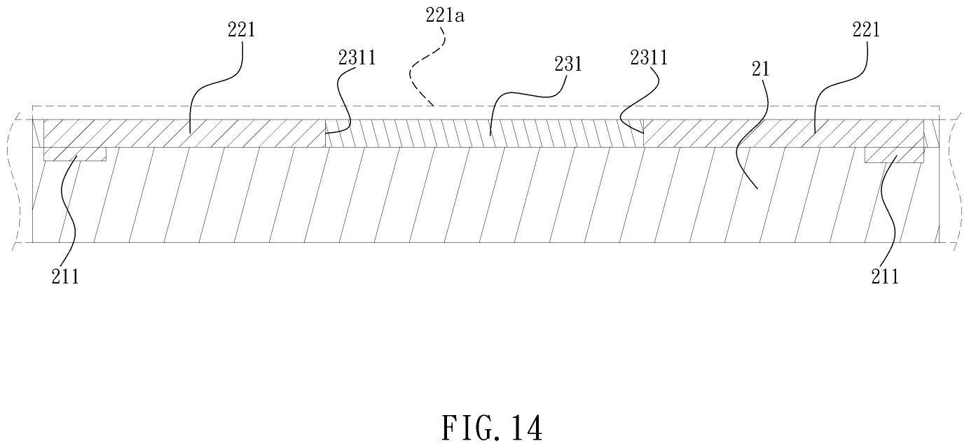

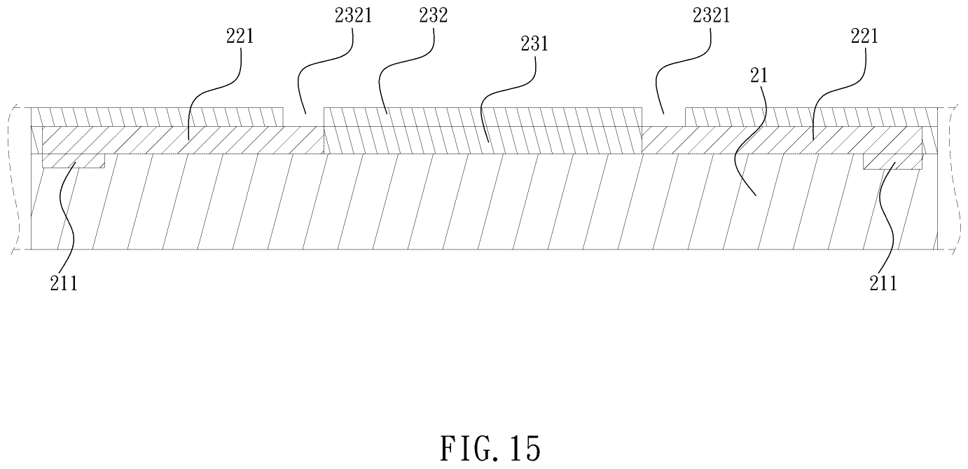

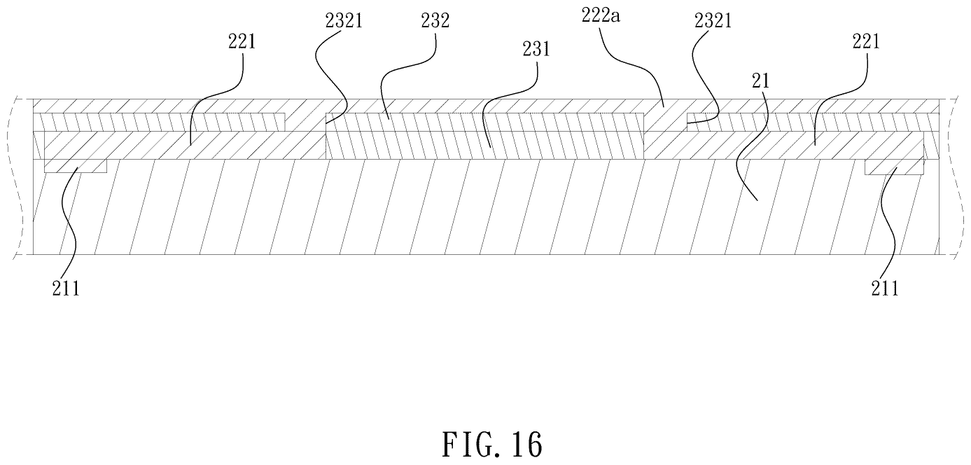

A method of manufacturing the chip 20 further includes the following steps.
Step S1: providing a wafer 3 having a plurality of dies 21, as shown in FIG. 11. Each of the dies 21 is provided with at least one die pad 211,
Step S2: disposing a first dielectric layer 231 over the dies 21 and forming at least one slot 2311 on the first dielectric layer 231, as shown in FIG. 12.
Step S3: filling a metal paste 221a into the slot 2311 of the first dielectric layer 231 and allowing a level of the metal paste 221a higher than a surface of the first dielectric layer 231, as shown in FIG. 13.
Step S4: grinding the metal paste 221a with the level higher than the surface of the surface of the first dielectric layer 231 to make a surface of the metal paste 221a flush with the surface of the first dielectric layer 231 and form a plurality of first conductive circuits 221, as shown in FIG. 14. The first conductive circuits 221 are electrically connected to the die pads 211 of the dies 21.
Step S5: arranging a second dielectric layer 232 over the first dielectric layer 231 and forming at least one slot 2321 on the second dielectric layer 232, as shown in FIG. 15.
Step S6: filling a metal paste 222a into the slot 2321 of the second dielectric layer 232 and allowing a level of the metal paste 222a higher than a surface of the second dielectric layer 232, as shown in FIG. 16.
Step S7: grinding the metal paste 222a with the level higher than the surface of the surface of the second dielectric layer 232 to make a surface of the metal paste 222a flush with the surface of the second dielectric layer 232 and form a plurality of second conductive circuits 222, as shown in FIG. 10. The second conductive circuits 222 are electrically connected to the first conductive circuits 221.
Step S8: performing cutting and diving the wafer 3 into a plurality of chips 20, as shown in FIG. 10. The first conductive circuits 221 and the second conductive circuits 222 are combined to form a plurality of chip conductive circuits 22. A chip dielectric layer 23 is formed by the first dielectric layer 231 and the second dielectric layer 232.

Refer to FIG. 10, both of the metal paste 221a and the metal paste 222a which respectively form the first conductive circuits 221 and the second conductive circuits 222 include silver paste, nano-scale silver paste, copper paste, and nano-scale copper paste.

Refer to FIG. 2, the substrate includes a silicon substrate, a glass substrate, and a ceramic substrate.

Refer to FIG. 6, the metal paste 40a which forms the conductive circuits 40 includes silver paste, nano-scale silver paste, copper paste, and nano-scale copper paste.

Refer to FIG. 3, the first chip surface 25 of the chip 20 is disposed on the second surface 12 of the substrate 10 by a die attach film (DAF) 80.

Compared with FOWLP technology available now, the present FOWLP unit 1 has the following advantages.
1 The FOWLP unit 1 is produced by the steps S3, S4 and S5 of the present method which not only helps in reduction of the thickness of the packaging unit, but also reduces cost by the simplified process. The use efficiency and reliability of the FOWLP unit 1 are improved effectively.
2 The steps S2, S4 and S5 of the method of manufacturing the FOWLP are not involved in chemical plating or electroplating available now so that cost and contamination generated during the manufacturing process can be reduced.
3 The chip 20 of the present invention is produced by the step S3-5 of the RDL technology. Thus the problem of the FOWLP technology available now including focus of the design on the die, without the design specific to the chip (formed by cutting of the wafer after completing RDL on the chip) can be solved. Thereby the products have become more diversified.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A fan-out wafer level packaging (FOWLP) unit comprising
a substrate provided with a first surface and a second surface opposite to the first surface;
at least one chip having a die, a plurality of chip conductive circuits, a chip dielectric layer, a plurality of chip bonding pads, a first chip surface, and a second chip surface; wherein the chip is arranged at the substrate by the first chip surface; wherein the chip bonding pads are disposed on the second chip surface and a range perpendicular to the second chip surface of the chip is defined as a chip area; wherein the die is provided with at least one die pad so that the die is electrically connected with the outside through the die pad, the chip conductive circuits, and the chip bonding pads in turn;
an dielectric layer mounted to the second surface of the substrate and covering the chip; at least one slot extending horizontally formed on the dielectric layer and used for allowing the corresponding chip bonding pad to be exposed;
at least one conductive circuit formed by a metal paste filled into the slots; wherein the conductive circuit is electrically connected to the chip bonding pads; and
an outer protective layer arranged over the dielectric layer and the conductive circuit and having a plurality of openings; wherein at least one of the openings is located around the chip area on the second chip surface of the chip;
wherein the conductive circuit is exposed through the opening correspondingly to form a bonding pad in the openings; wherein the chip is electrically connected with the outside through the chip bonding pads, the conductive circuit, and the bonding pads located around the chip area on the second chip surface of the chip; thereby the FOWLP unit is formed;
wherein a method of manufacturing the FOWLP unit comprising the steps of:
Step S1: providing a substrate; wherein the substrate having a first surface and a second surface opposite to each other;
Step S2: disposing a plurality of chips on the second surface of the substrate with an interval between the two adjacent chip; wherein the chip consists of a die, a plurality of chip conductive circuits, a chip dielectric layer, a plurality of chip bonding pads, a first chip surface, and a second chip surface; wherein the chip is arranged at the substrate by the first chip surface; wherein the chip bonding pads are disposed on the second chip surface and a range perpendicular to the second chip surface of the chip is defined as a chip area; wherein the die is provided with at least one die pad; the die is electrically connected with the outside through the die pad, the chip conductive circuit, and the chip bonding pads in turn; wherein a method of manufacturing the chip further includes the steps of providing a wafer having a plurality of dies each of which is provided with at least one die pad; then disposing a first dielectric layer over the dies and forming at least one slot on the first dielectric layer; next filling a metal paste into the slot of the first dielectric layer and allowing a level of the metal paste higher than a surface of the first dielectric layer; later grinding the metal paste with the level higher than the surface of the surface of the first dielectric layer to make a surface of the metal paste flush with the surface of the first dielectric layer and form a plurality of first conductive circuits; wherein the first conductive circuits are electrically connected to the die pads of the dies; then arranging a second dielectric layer over the first dielectric layer and forming at least one slot on the second dielectric layer; next filling a metal paste into the slot of the second dielectric layer and allowing a level of the metal paste higher than a surface of the second dielectric layer; later grinding the metal paste with the level higher than the surface of the surface of the second dielectric layer to make a surface of the metal paste flush with the surface of the second dielectric layer and form a plurality of second conductive circuits; wherein the second conductive circuits are electrically connected to the first conductive circuits; and lastly performing cutting and diving the wafer into a plurality of chips; wherein a plurality of chip conductive circuits is formed by the first conductive circuits and the second conductive circuits; wherein a chip dielectric layer is formed by the first dielectric layer and the second dielectric layer;
Step S3: disposing a dielectric layer on the second surface of the substrate and allowing the dielectric layer covering the chip; wherein the dielectric layer is provided with at least one slot extending in a horizontal direction and used for allowing the chip bonding pad to be exposed;
Step S4: filling a metal paste into the slot of the dielectric layer and allowing a level of the metal paste higher than a surface of the dielectric layer;
Step S5: grinding the metal paste with the level higher than the surface of the dielectric layer to make a surface of the metal paste flush with the surface of the dielectric layer and form a plurality of conductive circuits;
Step S6: paving an outer protective layer over the dielectric layer;
Step S7: forming a plurality of openings on the outer protective layer and allowing at least one of the openings to be located around the chip area on the second chip surface of the chip so that the conductive circuits are exposed through the openings to form a bonding pad in each of the openings; and
Step S8: performing cutting to form a plurality of FOWLP units.

2. The FOWLP unit as claimed in claim 1, wherein a bump is mounted in each of the openings and disposed on the bonding pad.

3. The FOWLP unit as claimed in claim 2, wherein a solder ball is disposed on each of the bumps.

4. The FOWLP unit as claimed in claim 3, wherein the FOWLP unit is electrically connected and mounted to a printed circuit board (PCB) by the solder balls.

5. The FOWLP unit as claimed in claim 1, wherein the metal pastes which form the first conductive circuits and the second conductive circuits include silver paste, nano-scale silver paste, copper paste, and nano-scale copper paste.

6. The FOWLP unit as claimed in claim 1, wherein the substrate includes a silicon substrate, a glass substrate, and a ceramic substrate.

7. The FOWLP unit as claimed in claim 1, wherein the metal paste which forms the conductive circuits includes silver paste, nano-scale silver paste, copper paste, and nano-scale copper paste.

8. The FOWLP unit as claimed in claim 1, wherein the first chip surface of the chip is disposed on the second surface of the substrate by a die attach film (DAF).
